(19) United States
(12) Patent Application Publication
(10) Pub. No.: US 2022/0321809 A1
(43) Pub. Date: Oct. 6, 2022

(54) DIFFERENTIAL ACTIVE PIXEL

(71) Applicant: Allegro MicroSystems, LLC, Manchester, NH (US)

(72) Inventors: Charles Myers, Portland, OR (US); Adam Lee, Portland, OR (US)

(73) Assignee: Allegro MicroSystems, LLC, Manchester, NH (US)

(21) Appl. No.: 17/656,977

(22) Filed: Mar. 29, 2022

Related U.S. Application Data
(60) Provisional application No. 63/167,876, filed on Mar. 30, 2021.

(51) Int. Cl. H04N 5/365; H03F 3/45; H04N 5/3745; G01J 1/44

(52) U.S. Cl. CPC H04N 5/3651; H03F 3/45475; H04N 5/37457; G01J 1/44; H04N 5/361

(57) ABSTRACT

Methods and apparatus for a pixel system for providing power supply noise rejection. A photodetector has a first terminal coupled to a voltage supply and a second terminal and a differential transimpedance amplifier has a first input coupled to the second terminal of the photodetector. The differential transimpedance amplifier is configured to convert a singled ended output on the second terminal of the photodetector to a differential signal. A bias circuit is coupled to the differential transimpedance amplifier to bias the differential transimpedance amplifier and the photodetector.

### CROSS REFERENCE TO RELATED APPLICATIONS

The present application claims the benefit of U.S. Provisional Patent Application No. 63/167,876 filed on Mar. 30, 2021, which is incorporated herein by reference.

### SUMMARY

Methods and apparatus of the disclosure provide a differential active pixel front-end for minimizing power supply noise, for example. Embodiments of the disclosure provide significant power supply noise rejection immunity. This is beneficial because of the high gain on the pixel front-end that amplifies any noise on the input. The use of a differential analog front-end increases sensitivity allowing longer ranging and lowering optical source power requirements. In some applications, the lowered power requirements are desirable as the power is limited by eye safety requirements.

In one aspect, a pixel system for providing power supply noise rejection comprises: a photodetector having a first terminal coupled to a voltage supply and a second terminal; a differential transimpedance amplifier having a first input coupled to the second terminal of the photodetector, wherein the differential transimpedance amplifier is configured to convert a singled ended output on the second terminal of the photodetector to a differential signal; and a bias circuit coupled to the differential transimpedance amplifier to bias the differential transimpedance amplifier and the photodetector.

A pixel system can further include one or more of the following features: a tuning capacitor having first and second terminals, wherein a second input of the differential transimpedance amplifier is coupled to a second terminal of the tuning capacitor, the differential transimpedance amplifier comprises a RTIA, CTIA, CTIA and/or shaper, the photodetector comprises a photodiode, the bias circuit is configured to maintain selected respective first and second bias voltages at the first input and a second input of the differential transimpedance amplifier with a feedback network coupled to the differential transimpedance amplifier, the selected bias voltages comprise selected common mode voltage bias levels, the first bias voltage is configured to define a bias voltage on the photodetector, which comprises a photodiode, the first bias voltage is configured to force a single-ended current from the photodiode into a differential output voltage from the differential transimpedance amplifier, the feedback network comprises first and second resistors coupled across the respective differential outputs and first and second inputs of the differential transimpedance amplifier, a tuning capacitor having first and second terminals, wherein a second input of the differential transimpedance amplifier is coupled to a second terminal of the tuning capacitor, wherein the tuning capacitor has a capacitance matched to a capacitance of the photodetector, the bias circuit forms part of a pixel, photodetectors and further bias circuits configured to provide independent biasing of pixel photodetectors in an array of photodetectors, at least one clamping diode coupled between the input and an output of the differential transimpedance amplifier, the system is configured such that when an aggregate diode forward voltage drop across the at least one clamping diode is exceeded, at least one clamping diode conducts current forcing the input of the differential transimpedance amplifier to conduct current to the output of the differential transimpedance amplifier, the system is further configured such that the current from the input to the output of the differential transimpedance amplifier modifies an output voltage of the differential transimpedance amplifier and by-way of the common-mode feedback modifies the bias of the differential transimpedance amplifier to force a portion of the input-output shorted current into a power supply though the differential transimpedance amplifier, a damage threshold exceedance detection circuit to detect when the photodetector provides a photo-current input above a threshold, and/or the damage threshold exceedance detection circuit comprises at least one clamping diode coupled between the input and an output of the differential transimpedance amplifier, wherein the damage threshold exceedance detection circuit includes a latch to store an alert.

In another aspect, a method comprises: in a pixel system for providing power supply noise rejection, employing a photodetector having a first terminal coupled to a voltage supply and a second terminal; employing a differential transimpedance amplifier having a first input coupled to the second terminal of the photodetector, wherein the differential transimpedance amplifier is configured to convert a singled ended output on the second terminal of the photodetector to a differential signal; and employing a bias circuit coupled to the differential transimpedance amplifier to bias the differential transimpedance amplifier and the photodetector.

A method can further include one or more of the following features: a tuning capacitor having first and second terminals, wherein a second input of the differential transimpedance amplifier is coupled to a second terminal of the tuning capacitor, the differential transimpedance amplifier comprises a RTIA, CTIA, CTIA and/or shaper, the photodetector comprises a photodiode, the bias circuit is configured to maintain selected respective first and second bias voltages at the first input and a second input of the differential transimpedance amplifier with a feedback network coupled to the differential transimpedance amplifier, the selected bias voltages comprise selected common mode voltage bias levels, the first bias voltage is configured to define a bias voltage on the photodetector, which comprises a photodiode, the first bias voltage is configured to force a single-ended current from the photodiode into a differential output voltage from the differential transimpedance amplifier, the feedback network comprises first and second resistors coupled across the respective differential outputs and first and second inputs of the differential transimpedance amplifier, a tuning capacitor having first and second terminals, wherein a second input of the differential transimpedance amplifier is coupled to a second terminal of the tuning capacitor, wherein the tuning capacitor has a capacitance matched to a capacitance of the photodetector, the bias circuit forms part of a pixel, photodetectors and further bias circuits configured to provide independent biasing of pixel photodetectors in an array of photodetectors, at least one clamping diode coupled between the input and an output of the differential transimpedance amplifier, the system is configured such that when an aggregate diode forward voltage drop across the at least one clamping diode is exceeded, at least one clamping diode conducts current forcing the input of the differential transimpedance amplifier to conduct current to the output of the differential transimpedance amplifier, the system is further configured such that the current from the input to the output of the differential transimpedance amplifier modifies an output voltage of the differential transimpedance amplifier and by-way of the common-mode feedback modifies the bias of the differential transimpedance amplifier to force a portion of the input-output shorted current into a power supply though the differential transimpedance amplifier, a damage threshold exceedance detection circuit to detect when the photodetector provides a photo-current input above a threshold, and/or the damage threshold exceedance detection circuit comprises at least one clamping diode coupled between the input and an output of the differential transimpedance amplifier, wherein the damage threshold exceedance detection circuit includes a latch to store an alert.

In another aspect, a pixel system for capturing active imaging data comprises: a photodetector having a first terminal coupled to a voltage supply and a second terminal; a differential transimpedance amplifier having a first input coupled to the second terminal of the photodetector; and a voltage discriminator having an input coupled to an output of the differential transimpedance amplifier and an output.

A pixel system for capturing active imaging data can further include one or more of the following features: a time-to-digital converter (TDC) having an input coupled to the output of the voltage discriminator and an output to generate a signal corresponding to a time of an event detected by the voltage discriminator, the TDC is configured to generate an output signal corresponding to an arrival of a pulse from the photodetector in response to receiving photonic energy, the output signal has a width corresponding to a width and/or amplitude of the pulse from the photodetector, the width of the output signal corresponds to amount of time the pulse from the photodetector is a above a threshold, the threshold comprises an output from a threshold generator circuit, the threshold generator circuit is only coupled to one of the voltage discriminator inputs, a transition of the TDC output signal corresponds to an arrival time of the photonic energy on the photodetector, the photonic energy comprises light transmitted by a LIDAR system, the differential transimpedance amplifier is configured to convert a single-ended current pulse signal from the photodetector on the first input of the differential transimpedance amplifier to a differential output signal, a voltage gain module to receive an output of the differential transimpedance amplifier and generate an amplified differential output to the voltage discriminator, storage capacitors before and/or after the voltage gain module and switches, the differential transimpedance amplifier output corresponds to a response from the photodetector due to transient photonic energy from, signal return and background and dark current, and/or switches configured to store background offset voltages on the capacitors and apply the offset voltages to the voltage discriminator to cancel the offset voltages, and 2) applying a threshold for active returns from the photodetector, wherein the threshold is set relative to the offset voltages.

In another aspect, a pixel system for capturing passive imaging data comprises: a photodetector having a first terminal coupled to a voltage supply and a second terminal; a transimpedance amplifier having a first input coupled to the second terminal of the photodetector; a voltage discriminator having an input coupled to an output of the transimpedance amplifier and an output; and a ramp circuit to generate a ramp signal on the input of the voltage discriminator.

A pixel system for capturing passive imaging data can further include one or more of the following features: a time-to-digital converter (TDC) having an input coupled to the output of the voltage discriminator and an output to generate a signal corresponding to a time of an event detected by the voltage discriminator, the output of the transimpedance amplifier comprises differential outputs to the voltage discriminator, a tuning capacitor coupled to a second input of the transimpedance amplifier, which is comprises a differential transimpedance amplifier, the transimpedance amplifier is configured to generate an output voltage proportional to a background current of the photodetector, a first capacitor coupled between the ramp circuit and the first input of the voltage discriminator, the ramp circuit includes a current source to charge the first capacitor, the current source is configured to output a constant current signal to the first capacitor, at least one first switch coupled between the current source and the voltage discriminator, the voltage discriminator output is configured to transition at a relative time corresponding to a time for signal from the current source to overcome a differential signal at the input of the voltage discriminator, the voltage discriminator output is configured to transition at a relative time corresponding to a time representing a passive background illumination level, the transimpedance amplifier comprises a differential transimpedance amplifier having a second input coupled to a voltage reference, input of the voltage discriminator comprises first and second inputs to receive a differential output from the transimpedance amplifier, and wherein the ramp circuit is coupled to only one of the first and second inputs of the voltage discriminator, input of the voltage discriminator comprises first and second inputs, wherein the output from the transimpedance amplifier is coupled to the first input of the voltage discriminator, and wherein the ramp circuit is coupled to the second input of the voltage discriminator, and/or the relative times between pixel events that are directly proportional to gain variation under uniform illumination.

In another aspect, a method for capturing active imaging data comprises: employing a photodetector having a first terminal coupled to a voltage supply and a second terminal; employing a differential transimpedance amplifier having a first input coupled to the second terminal of the photodetector; and employing a voltage discriminator having an input coupled to an output of the differential transimpedance amplifier and an output.

A method for capturing active imaging data can further include one or more of the following features: a time-to-digital converter (TDC) having an input coupled to the output of the voltage discriminator and an output to generate a signal corresponding to a time of an event detected by the voltage discriminator, the TDC is configured to generate an output signal corresponding to an arrival of a pulse from the photodetector in response to receiving photonic energy, the output signal has a width corresponding to a width and/or amplitude of the pulse from the photodetector, the width of the output signal corresponds to amount of time the pulse from the photodetector is a above a threshold, the threshold comprises an output from a threshold generator circuit, the threshold generator circuit is only coupled to one of the voltage discriminator inputs, a transition of the TDC output signal corresponds to an arrival time of the photonic energy on the photodetector, the photonic energy comprises light transmitted by a LIDAR system, the differential transimpedance amplifier is configured to convert a single-ended current pulse signal from the photodetector on the first input of the differential transimpedance amplifier to a differential output signal, a voltage gain module to receive an output of the differential transimpedance amplifier and generate an amplified differential output to the voltage discriminator, storage capacitors before and/or after the voltage gain module and switches, the differential transimpedance amplifier output corresponds to a response from the photodetector due to transient photonic energy from, signal return and background and dark current, and/or switches configured to store background offset voltages on the capacitors and apply the offset voltages to the voltage discriminator to cancel the offset voltages, and 2) applying a threshold for active returns from the photodetector, wherein the threshold is set relative to the offset voltages.

In another aspect, a method for capturing passive imaging data comprises: employing a photodetector having a first terminal coupled to a voltage supply and a second terminal; employing a transimpedance amplifier having a first input coupled to the second terminal of the photodetector; employing a voltage discriminator having an input coupled to an output of the transimpedance amplifier and an output; and employing a ramp circuit to generate a ramp signal on the input of the voltage discriminator.

A method for capturing passive imaging data can further include one or more of the following features: a time-to-digital converter (TDC) having an input coupled to the output of the voltage discriminator and an output to generate a signal corresponding to a time of an event detected by the voltage discriminator, the output of the transimpedance amplifier comprises differential outputs to the voltage discriminator, a tuning capacitor coupled to a second input of the transimpedance amplifier, which is comprises a differential transimpedance amplifier, the transimpedance amplifier is configured to generate an output voltage proportional to a background current of the photodetector, a first capacitor coupled between the ramp circuit and the first input of the voltage discriminator, the ramp circuit includes a current source to charge the first capacitor, the current source is configured to output a constant current signal to the first capacitor, at least one first switch coupled between the current source and the voltage discriminator, the voltage discriminator output is configured to transition at a relative time corresponding to a time for signal from the current source to overcome a differential signal at the input of the voltage discriminator, the voltage discriminator output is configured to transition at a relative time corresponding to a time representing a passive background illumination level, the transimpedance amplifier comprises a differential transimpedance amplifier having a second input coupled to a voltage reference, input of the voltage discriminator comprises first and second inputs to receive a differential output from the transimpedance amplifier, and wherein the ramp circuit is coupled to only one of the first and second inputs of the voltage discriminator, input of the voltage discriminator comprises first and second inputs, wherein the output from the transimpedance amplifier is coupled to the first input of the voltage discriminator, and wherein the ramp circuit is coupled to the second input of the voltage discriminator, and/or the relative times between pixel events that are directly proportional to gain variation under uniform illumination.

In another aspect, a pixel system for correction of non-uniform photo-detector and pixel gains comprises: a photodetector having a first terminal coupled to a voltage supply and a second terminal; a differential transimpedance amplifier having a first input coupled to the second terminal of the photodetector; a bias circuit coupled to the differential transimpedance amplifier to set common mode feedback for the differential transimpedance amplifier and to set bias of the photodetector for correcting non-uniform photodetector gain; and a digital-to-analog converter coupled to the bias circuit, the digital-to-analog converter configured to output multiple discrete voltage levels.

A pixel system for correction of non-uniform photo-detector and pixel gains can further include one or more of the following features: a number of the multiple discrete voltage levels corresponds to an integer power of two, a multiplexer to receive input from the digital-to-analog converter and to select a signal for the bias circuit, a global DAC level generator external to the pixel for generating a coarse set of voltages and a fine DAC level generator internal to the pixel for generating a voltage with finer resolution than that provided by the global DAC level generator, a series of muxes coupled to the bias circuit for selecting DAC output voltages for approximating an interpolated bias voltage setting between the discretely available DAC settings in a DAC voltage distribution network, the digital-to-analog converter is coupled to a plurality of pixels, the voltage levels are programmable, a DAC voltage distribution network for the multiple discrete voltage levels, the DAC voltage distribution network comprises cascaded muxes; and/or an entirety of the DAC is contained within the pixel.

In another aspect, a method for correction of non-uniform photo-detector and pixel gains comprises: employing a photodetector having a first terminal coupled to a voltage supply and a second terminal; employing a differential transimpedance amplifier having a first input coupled to the second terminal of the photodetector; employing a bias circuit coupled to the differential transimpedance amplifier to set common mode feedback for the differential transimpedance amplifier and to set bias of the photodetector for correcting non-uniform photodetector gain; and employing a digital-to-analog converter coupled to the bias circuit, the digital-to-analog converter configured to output multiple discrete voltage levels.

A method for correction of non-uniform photo-detector and pixel gains can further include one or more of the following features: a number of the multiple discrete voltage levels corresponds to an integer power of two, a multiplexer to receive input from the digital-to-analog converter and to select a signal for the bias circuit, a global DAC level generator external to the pixel for generating a coarse set of voltages and a fine DAC level generator internal to the pixel for generating a voltage with finer resolution than that provided by the global DAC level generator, a series of muxes coupled to the bias circuit for selecting DAC output voltages for approximating an interpolated bias voltage setting between the discretely available DAC settings in a DAC voltage distribution network, the digital-to-analog converter is coupled to a plurality of pixels, the voltage levels are programmable, a DAC voltage distribution network for the multiple discrete voltage levels, the DAC voltage distribution network comprises cascaded muxes; and/or an entirety of the DAC is contained within the pixel.

### BRIEF DESCRIPTION OF THE DRAWINGS

The foregoing features of this disclosure, as well as the disclosure itself, may be more fully understood from the following description of the drawings in which:

FIG. 1 is a schematic representation of a detection system having a common mode bias module;

FIG. 1A is an example circuit implementation of the detection system of FIG. 1;

FIG. 1B is an example circuit implementation of a detector having a common mode feedback circuit;

FIG. 2 is a circuit diagram of an example active detection circuit;

FIG. 3 is a schematic representation of a passive detection circuit;

FIG. 4 is a schematic representation of an alternative passive detection circuit;

FIG. 5 is a schematic representation of an alternative passive detection circuit;

FIG. 6 is a schematic representation of an alternative passive detection circuit;

FIG. 7 is a schematic representation of an active detection circuit;

FIG. 8 is a schematic representation of a detection circuit having offset correction;

FIG. 9 is a schematic representation of an alternative detection circuit having offset correction;

FIG. 10 is a schematic representation of an example per-pixel biasing system;

FIG. 11 is a schematic representation of an example voltage selection network for the per-pixel biasing system of FIG. 10;

FIG. 11A is a schematic representation of per-pixel biasing system having an example global DAC level configuration;

FIG. 12 is a schematic representation of a replica bias system having interpolated DAC settings;

FIG. 13 is a schematic representation of a passive detection system having non-uniformity measurement for pixel calibration;

FIG. 14 is a circuit diagram of an example detection system having pixel damage protection; and

FIG. 15 is a circuit diagram of an example detection system having damage threshold exceedance.

### DETAILED DESCRIPTION

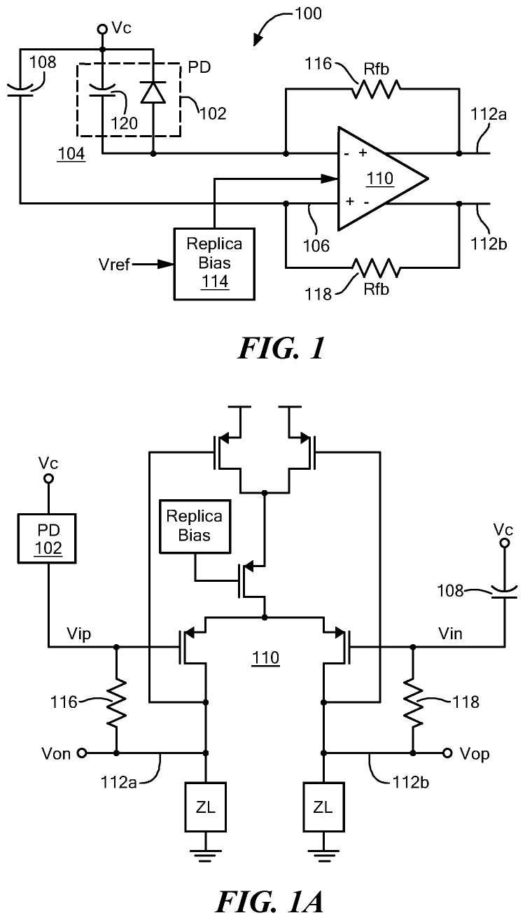

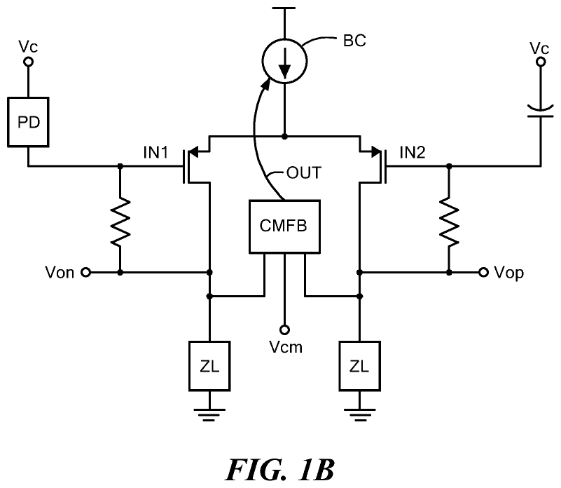

FIG. 1 shows an example embodiment 100 to convert an inherently single-ended sensor 102, which is shown as a photo detector diode, into a differential signal generation source. FIG. 1A shows an example circuit implementation of the embodiment 100 of FIG. 1. Example embodiments of a differential front-end may include the photo-detector (PD) diode 102 and a capacitive matching structure 104 in which, for example, a differential input 106 not connected to the photo-detector diode 102 is connected to a matched or tuned capacitor 108 coupled to the same power supply as the photo-diode. The circuit 100 can further include a differential resistive-transimpedance amplifier (RITA) 110 for converting the single-ended current input into a differential voltage at its output 112a,b. The circuit 100 can further include a replica bias module 114 for biasing the differential RITA 110 to maintain the desired bias voltages in the RTIA inputs via a feedback network, which can include respective feedback resistors 116, 118.

It is understood that the photo-detector diode 102 converts photon flux into electrical current flow. It is further understood that the capacitance shown may not be a separate capacitor, but rather an inherent capacitance 120 of the PD diode 102 which should be balanced in any differential structure.

In embodiments, capacitive matching may comprise a structure of metal routing identical to the metal routing used for connecting, for example, to either a monolithic photo-diode or a wafer-wafer or die-detector bonded photo-diode. In embodiments, the capacitance 120 of the photo-diode 102 is matched with a metal-metal capacitor 108 tuned to match the nominal capacitance of the photo-diode. In other embodiments, the photo-diode capacitance 120 can be matched with another diode (not shown) that is photo-insensitive having minimal dark current and matched capacitance behavior over a range of voltage biases.

The differential resistive transimpedance amplifier (RTIA) 110 can convert a single-ended current input into a differential voltage output 112a,b and may implement a common mode feedback circuit that works in concert with the replica bias 114 to force the inputs to hold a desired common-mode voltage at the RTIA 110 input. This common mode voltage defines the bias voltage on the photo-diode 102. The common mode circuit also forces the single-ended input current to develop a differential voltage at the outputs 112,a,b of the RTIA which is desirable for power supply and common mode noise suppression. The common mode feedback circuit employed also may have speed and size benefits and relies on the replica bias circuitry to set the desired common mode voltage while only handling the regulation of transient common mode input signals.

The replica bias circuit 114 may also provide a bias to the RTIA 110 that effectively sets the common mode input voltage of the RTIA. The replica bias circuit 114 may be implemented in a pixel with the RTIA 110 to minimize device mismatch and to further improve power supply noise immunity. This in-pixel replica bias circuit also allows independent biasing of pixel photo-diodes which is desirable for equalizing the gain, offset, and other behaviors of an array of pixel photo-diodes.

FIG. 1B shows an example common-mode feedback circuit CMFB in which the average value of the two inputs IN1, IN2 is compared to a common mode voltage reference Vcm and the output OUT of the CMFB circuit is controlling a bias control BC, such as a current source, which modifies the output common mode value (average value). The CMFB is configured to form a negative-feedback loop that servos the output common mode voltage to be matched to the common mode voltage reference. In the context of a differential active pixel amplifier, when a photo-current is generated by a photodiode PD, the output is reflected only at the Von node. The common-mode feedback circuit CMFB then responds to this shift in output common mode and servos the output common mode back to Vcm which produces a fully-differential output voltage at the output in response to the PD input current.

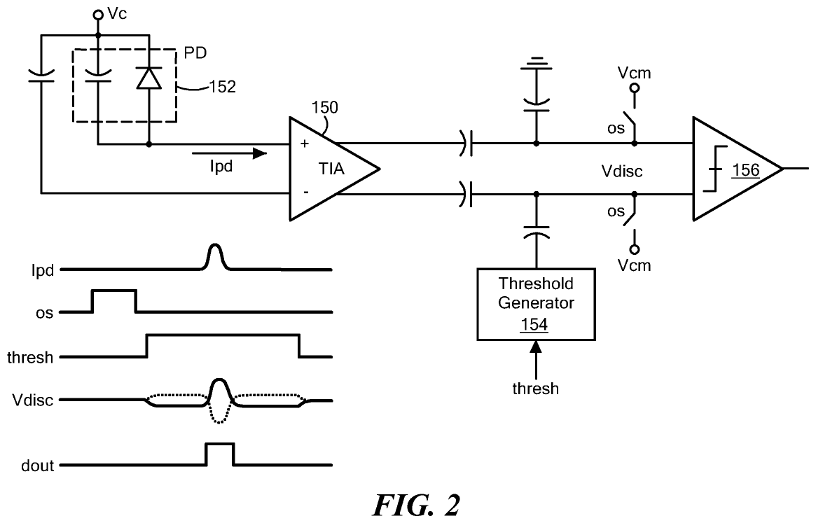

FIG. 2 shows an example circuit implementation for detecting transient current inputs from a photo-detector and producing a digital output pulse consistent with the arrival time of the current input pulse and with a width proportional to the width and/or amplitude of the current pulse. A differential transimpedance amplifier (TIA) 150 converts the active single-ended photo-current input pulse Ipd from a photodetector 152 into a differential output voltage pulse Vdisc. When the differential voltage pulse Vdisc exceeds a threshold injected by a threshold generator 154, a discriminator 156 detects this and produces a digital pulse dout with a width proportional to the time the differential signal is greater than the threshold. The rising edge of the digital output approximates the arrival time of the active transient photo-current pulse and the width of the digital output pulse is proportional to the amplitude of the active transient photo-current pulse. The rising and falling edges of the digital pulse can be timed with a time-to-digital converter (TDC). This imaging scheme is an active imaging system and is useful in any number of applications including range finding and LiDAR.

In another aspect, passive imaging data can be captured in an active pixel circuit. Having the ability to measure both active (transient) and passive (static) in the same pixel has significant advantages for manufacture, calibration, and/or system integration. Passive pixel measurement and operation is easier to implement than active pixel testing for production screening as uniform illumination or simple DC injection test modes are all that is required to effectively test photo-diode to output paths. Calibration is also simpler as gain calibration only requires a uniform light source across an imaging array instead of a uniform optical pulse. System integration is aided by passive mode as it allows for easier optical alignment in any mounting configurations where optical field of view must match other systems such as illumination source fields of view or alignment with system optical elements.

In example embodiments, passive imaging reuses pixel amplifier circuitry for active imaging thereby keeping power and noise at a minimum while allowing for finer pixel resolution and higher sensitivity in active modes.

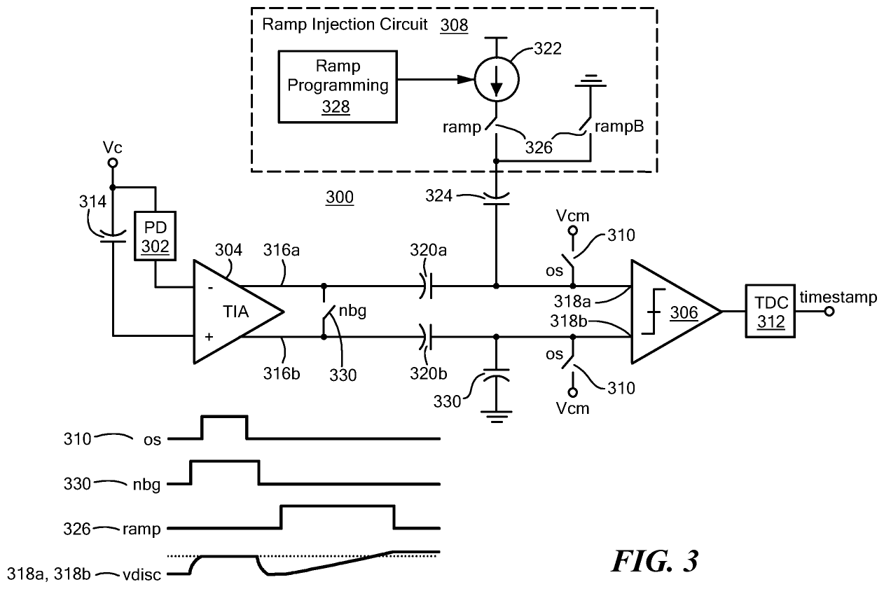

FIG. 3 shows an example embodiment of a passive imaging circuit 300 having a photo-detector (PD) diode 302 coupled to an input of a differential front end transimpedance amplifier 304 the outputs of which are provided to a voltage level discriminator 306. An auxiliary voltage ramp generation module 308 is coupled to one input of the voltage level discriminator 306. Control switches enable reconfiguration and operation of the pixel into passive measurement mode, as described more fully below. The output of the voltage level discriminator 306 is provided to a time-to-digital converter (TDC) 312.

In embodiments, the photo-detector (PD) diode 302 generates current proportional to the incident photon flux striking the PD. The PD has an inherent capacitance between the two terminals and may be matched with a capacitor 314 of the same impedance as the inherent capacitance of the PD to balance the differential circuit.

The front-end pixel transimpedance amplifier (TIA) 304 converts photo-diode current into voltage outputs 316a,b with additional gain. In embodiments, this conversion is achieved by way of a current to voltage stage in series with a voltage gain stage. The voltage gain stage is optional and improves the sensitivity of the detector system. Embodiments of the front-end TIA circuit 304 are configurable to produce a negative differential voltage proportional to the background photo-detector current.

The voltage level discriminator 306 compares first and second analog voltage inputs and produces a digital output whenever the positive input 318a exceeds the voltage of the negative input 318b. The output of the analog front end amplifying stage 304 is connected to the discriminator 306 either directly or through AC-coupling capacitors 320a,b. With the negative differential voltage input on the discriminator inputs 318a,b, a positive input must be provided with sufficient amplitude to overcome the negative input.

In embodiments, the auxiliary voltage ramp module 308 produces a voltage ramp at the positive discriminator input 318a triggered by a timing control signal, which may comprise, for example, a current source 322 producing constant current configured to flow into a capacitor 324. A switch 326 connects the current source 322 to the capacitor 324 controlled with a timing signal. The result of this configuration is that the voltage on the capacitor 324 rises at a rate proportional to the current setting. This current is electrically programmable 328 allowing modification of the voltage ramp rate. This structure may either be included in individual pixels, shared among groups of pixels, or configured as single structure delivering a ramp input to all pixels simultaneously. The circuit may also be implemented on the negative signal side of the input 318b coupled through capacitor 330 with a negative ramping direction with the same effect.

Control switches may perform several tasks. One switch set (not shown as internal to front-end amplifier) reconfigures the differential amplifier circuit so that static photo-current is represented as a negative differential value at the amplifier stage outputs. Other sets of switches 310, 330 control input capacitor sampling in an AC-coupled implementation (nbg,os). Another set of switches 326 controls the ramp operation (ramp).

The time-to-digital converter (TDC) 312 produces a digital output code proportional to the time of an event with respect to another system timing reference. When the ramp injection 308 is operational and moving on the positive discriminator input, at the point in time where the positive input becomes higher than the negative input, the discriminator 306 output transitions from low-to-high. This output transition is timed with the TDC 312 to produce a time stamp corresponding to the time it took for the ramp to overcome the negative differential voltage presented at the discriminator input 318a,b, which is derived from the static photo-diode 302 current and a measurement of the relative APD gain under uniform illumination.

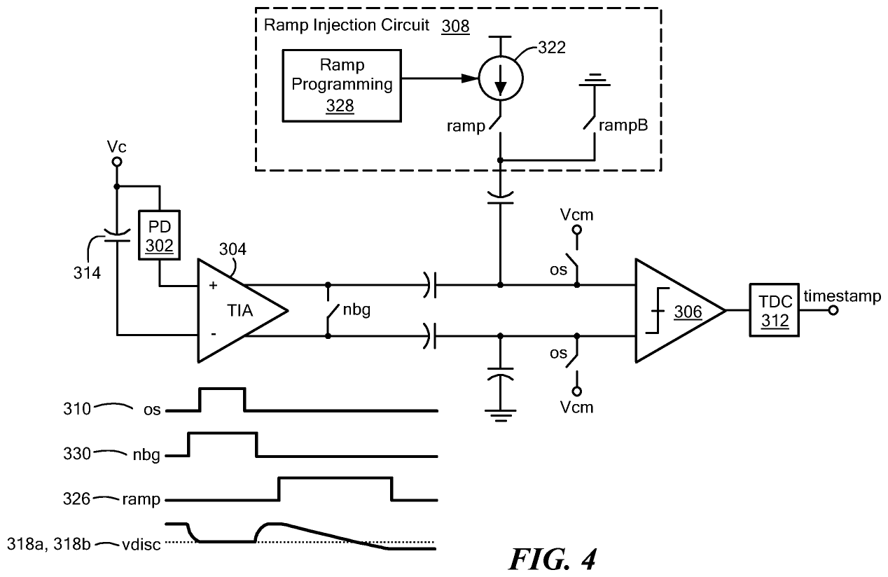

In other embodiments as shown in FIG. 4, the TIA 304 output is not inverted so that the ramp circuit 308 operates with a ramping high-to-low behavior or the low-to-high ramp circuit moves to the opposite discriminator 306 input. In this configuration the discriminator output transition from logical high-to-low is timed to represent the passive background illumination level.

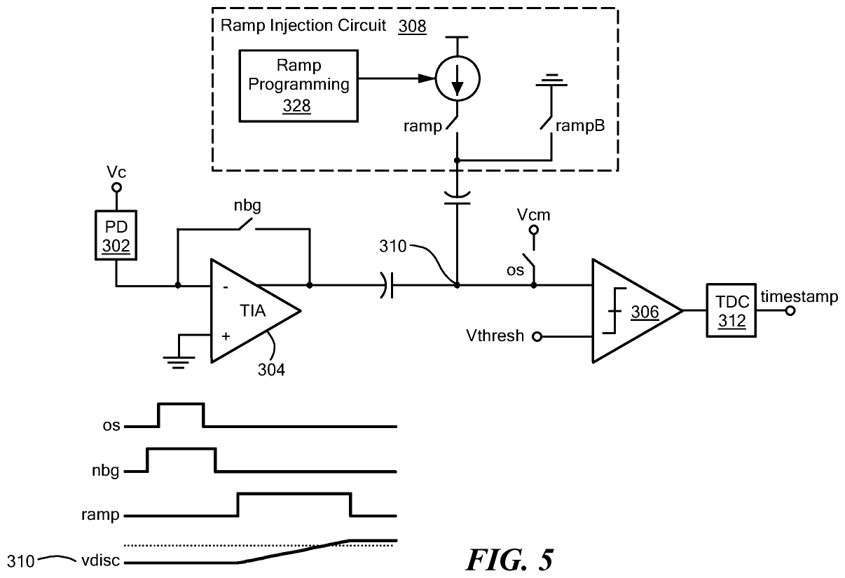

In other embodiments, as shown in FIG. 5, a circuit is implemented as a single-ended circuit reducing power supply noise immunity but reducing pixel area and thermal noise contributions. The implementation is the same with a ramping voltage injected onto the discriminator 306 input. The TDC 312 times when the input ramping voltage sufficiently counteracts the negative voltage (from the sampled bias condition) and the value crosses a set threshold voltage.

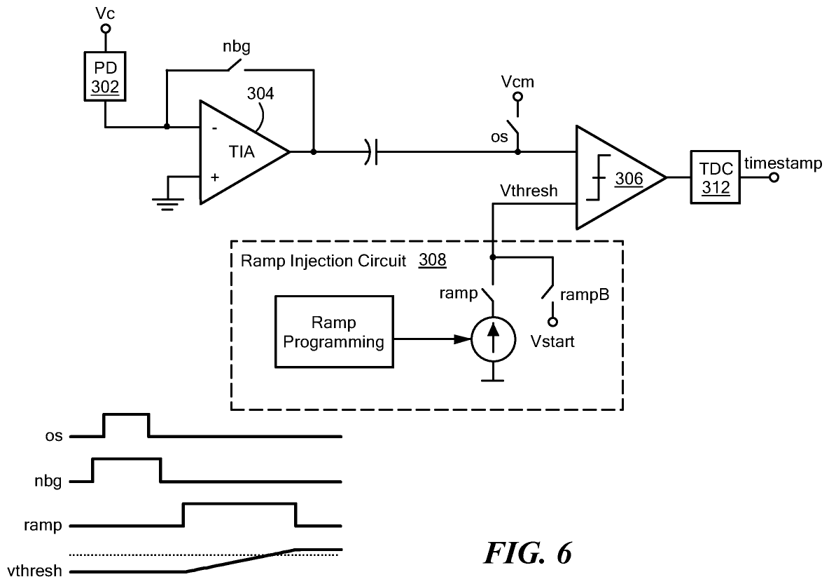

In other embodiments, as shown in FIG. 6, the circuit has a single-ended implementation with the ramp circuit 308 directly driving the negative discriminator 306 input instead of the threshold. In this configuration, the ramp voltage represents a changing discriminator threshold. The point where that threshold crosses the voltage level presented at the discriminator 306 input produces an edge that is timed by the TDC 312 and corresponds to the input background level. The ramp voltage can be configured to either move up or down depending on the whether the background current produces a positive or negative change in voltage at the discriminator input.

In the passive imaging embodiments described above, example circuits allow for a measured time stamp value that is proportional to photo-diode photo-current applied to the input of the pixel amplifier. These time stamps can then be used to construct a passive image representing the instantaneous flux at each pixel in the array of photo-detectors at the moment of the passive measurement.

In another aspect, a pixel background and dark current removal circuit is provided. In active imaging pixels, background and dark currents reduce the operable range of pixel event detection circuits. Further, variation in background and dark current may create difficulties in setting active detection sensitivity levels to achieve range or illumination power goals without becoming susceptible to excessive noise varying from pixel to pixel. Utilizing an AC-coupling connection with a capacitor between the photo-diode and the active amplifier inputs can remove some of these concerns but then introduce additional input loading which increases noise and reduces detector sensitivity. In embodiments, background removal stores background and dark current offsets in each pixel individually and deviations from that offset become the measured signal. This may simplify the problem of changing background images in dynamic scenes while maintaining maximum detector sensitivity.

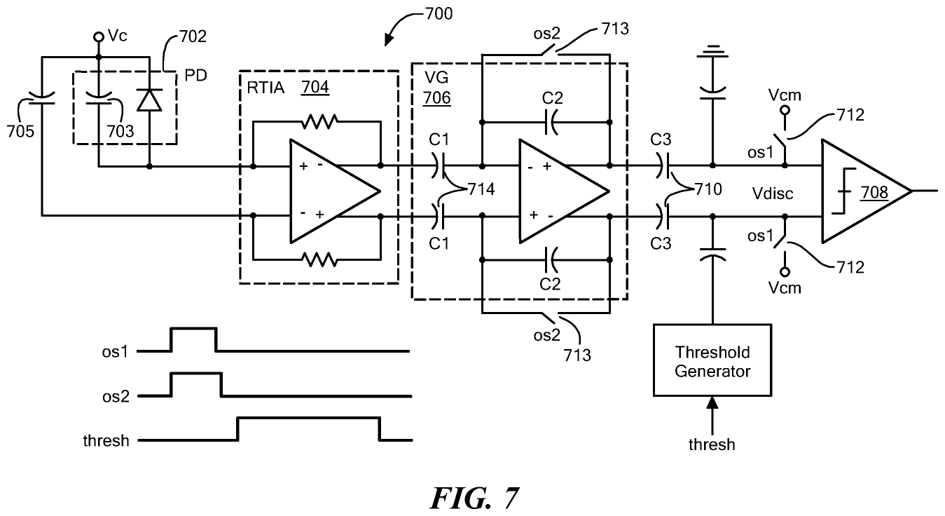

FIG. 7 shows an example background and dark current removal system 700 including a photo-detector diode 702 coupled to a differential resistive transimpedance amplifier 704. A differential voltage gain circuit 706 receives an input from the RTIA 704 and provides an output to a voltage discriminator 708. Background offset storage capacitors 710,714 can be coupled between the RTIA circuit 704, the voltage gain circuit 706 and the voltage discriminator 708. Timing control switches 712,713 can be provided for offset storage.

In embodiments, the photo-detector (PD) diode 702 generates current proportional to the incident photon flux striking the PD. The PD has an inherent capacitance 703 between the two terminals and may be matched with a capacitor 705 of the same value as the inherent capacitance of the PD to balance the differential circuit.

The differential resistive transimpedance amplifier (RTIA) 704 generates a differential voltage proportional to the input current. This is true for static background and dark current as well as transient currents associated with active returns.

The voltage gain circuit (VG) 706 which follows the differential RTIA 704 amplifies this differential voltage signal and presents it to the capacitors 710 at the input of the voltage discriminator 708. This gain stage has some inherent offset due to device manufacturing variation. This offset will effectively reduce the sensitivity of the pixel event detection circuit as it will require a high threshold setting to compensate for the gain circuit variation from pixel to pixel.

The background and offset storage capacitors pairs 710 may either be serially connected in an AC-coupled configuration to the voltage discriminator 708 inputs or directly coupled to ground from the inputs. These capacitors store the background offsets converted to a differential voltage and amplified by the voltage gain stage. Further utilizing input AC-coupling capacitor pairs 714 in the voltage gain stage 706 as offset and background storage improves the correction range by storing offsets before they are gained up by the VG stage 706.

The timing control switches toggle operations between storing background offsets and applying the offsets to the discriminator 708 inputs cancelling the offsets and allowing the circuit to only observe differences from that reference point. This is accomplished by driving the capacitor pairs 714 and/or 710 with the background level and connecting the opposite side of the capacitors to a reference voltage either generated by unity-gain amplifier configuration or direct connection to a reference voltage. Utilizing the unity-gain configuration for setting the reference voltage also stores the amplifier stage offset in the capacitor pair allowing cancellation of this error as well. The voltage difference is then sampled on the capacitors by opening switch pairs 712,713 in sequence. This sampling occurs only moments before the circuit is to be used for active return acquisition thereby ensuring that background and dark current values are the same between the sampling moment and the acquisition moment. After sampling, the values stored on the capacitors 710,714 cancel amplifier offset and background signal offset such that there is zero offset at the input of the discriminator 708. Shortly after this offset and background sampling, a programmable threshold offset is injected to one or both sides of the discriminator 708 inputs setting a required threshold that an active return must exceed to trigger the discriminator output.

The offset storage operation may also include the offset sampling and storage of discriminator input-referred offsets. These offsets are stored on the capacitors connected to the discriminator inputs and instead of the discriminator input switches 712 sampling a reference voltage, the discriminator is configured during osl to present the offset of the discriminator on the inputs. These inputs are then sampled and stored as a part of the offset storage operation and becomes the starting input voltages of the discriminator effectively removing contributions of the discriminator offset as well from the operation of the signal path.

In embodiments, the voltage level discriminator 708 compares two analog voltage inputs and produces a digital output whenever the positive input exceeds the voltage of the negative input. The output of the analog front end amplifying stage 706 is connected to the discriminator 708 either directly or through the AC-coupling capacitors 710. When the differential input exceeds an adjustable threshold, the digital output transitions and indicates an event has occurred. Later time-to-digital conversion measures this moment in time compared to a reference and provides a digital code representing the time of this event.

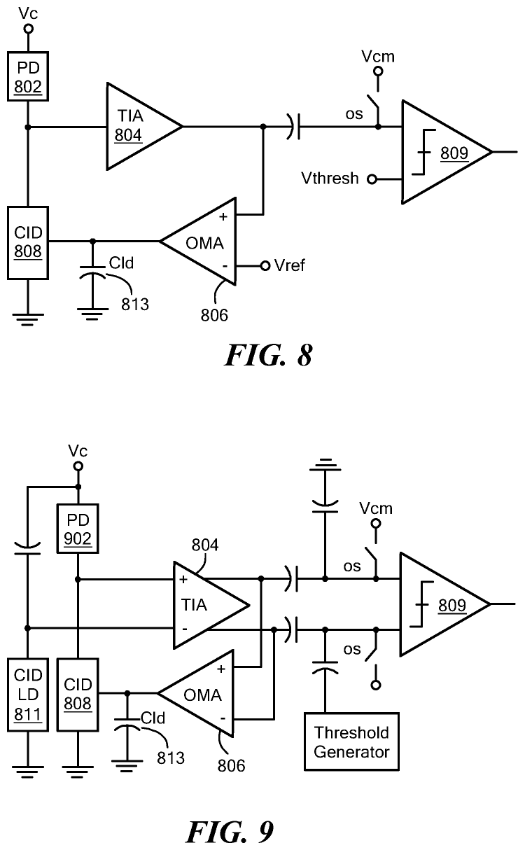

FIG. 8 shows an alternative embodiment for correcting background offset developed including a photo-diode 802 coupled to a differential or single-ended pixel front-end transimpedance amplifier 804 providing an input to a differential offset measurement amplifier 806. A front-end current injection device (CID) 808 receives an output from the differential offset measurement amplifier 806. The CID 808 is coupled to the shared input node between the photo-diode 802 and the TIA 804 for injecting positive or negative current. A voltage discriminator 809 is coupled to an output of the TIA 804.

In embodiments, the front-end pixel transimpedance amplifier (TIA) 804 converts input photo-current from the photo-diode 802 into a voltage that is either differential or single-ended. The instantaneous voltage is dependent on the background photo-current and dark current at the input of the amplifier 804.

The differential offset measurement amplifier (OMA) 806 measures the offset between either differential outputs or a single ended output and a reference voltage Vref. The output of the offset measurement amplifier 806 drives the current injection device 808 connected to the input of the front-end amplifier 804.

The front-end current injection device (CID) 808 injects current proportional to the output of the differential offset measurement amplifier 806. The system forms a loop that provides the required front-end current injection necessary to cancel the background current. In the differential configuration, an additional load matching device 811 may be added to match the additional loading of the CID on the PD node, as shown in FIG. 9. This is optional and will improve the power supply noise rejection of the circuit.

In embodiments, the circuit loop should have a relatively slow bandwidth compared to the active signal path in the forward direction so that the servo loop does not remove any active signal. The bandwidth reduction can be achieved by use of a filtering capacitor 813 in the output of the differential offset measurement amplifier 806.

In another aspect, a pixel gain non-uniformity correction circuit is provided. Avalanche photo-diodes have gain that is sensitive to bias conditions and varies from photo-diode to photo-diode. It is desirable to equalize the gain so that the performance across the array of photo-diodes in the design is uniform. In embodiments, sensitivity and noise performance are made uniform across the array. In some embodiments, other characteristics of photo-diodes, such as offset and dark current, may be equalized. In embodiments, photo-detector biases can be adjusted per photo-diode which will allow equalization of parameters that are sensitive the photo-diode bias voltage.

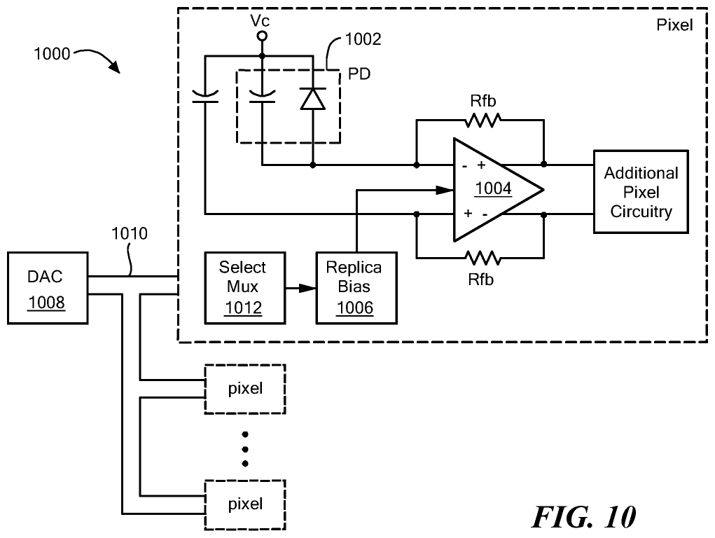

FIG. 10 shows an example per-pixel voltage biasing implementation 1000 including a photo-detector diode device 1002 coupled to a differential resistive transimpedance amplifier 1004 having common mode feedback. A replica bias circuit 1006 biases the RTIA 1004 common mode feedback. A range-programmable voltage DAC 1008 is coupled to a DAC voltage distribution network 1010. A per-pixel DAC voltage selection mux network 1012 can also be provided.

As noted above, the photo-detector (PD) diode 1002 converts photon flux into electrical current flow. The resistive transimpedance amplifier (RTIA) 1004 converts photo-diode current inputs into differential voltage outputs and maintains the photo-diode bias voltage by way of its common-mode feedback circuit.

In embodiments, the replica bias circuit 1006 biases the RTIA to effectively set in the input common mode voltage of the RTIA. This voltage is also the bias voltage of the photo-diode 1002 and therefore the replica bias circuit 1006 also sets the photo-diode bias voltage. In embodiments, the circuit is implemented per-pixel to allow per-pixel bias settings of the photo-diodes in the array of photo-diodes.

The range programmable DAC 1008 can provide multiple, discrete DAC voltage levels. The number of levels may be some power of 2 number of levels for convenience but can be any practical configuration of multiple voltage levels spaced uniformly in voltage or not uniformly in voltage. These levels are presented to a voltage delivery network for per-pixel DAC programming. The DAC 1008 voltage output range may also be adjustable by electrically programmable register as desired for each photo-diode technology, design, and application, for example.

The DAC voltage distribution network 1010 comprises a network of horizontal and/or vertical routes depending on array configuration delivering DAC voltages across a linear or two-dimensional array of pixels. The delivery network 1010 allows each pixel to have access to various DAC voltages and allows for independent selection of the desired DAC voltage for each individual pixel and thereby for each individual photo-diode.

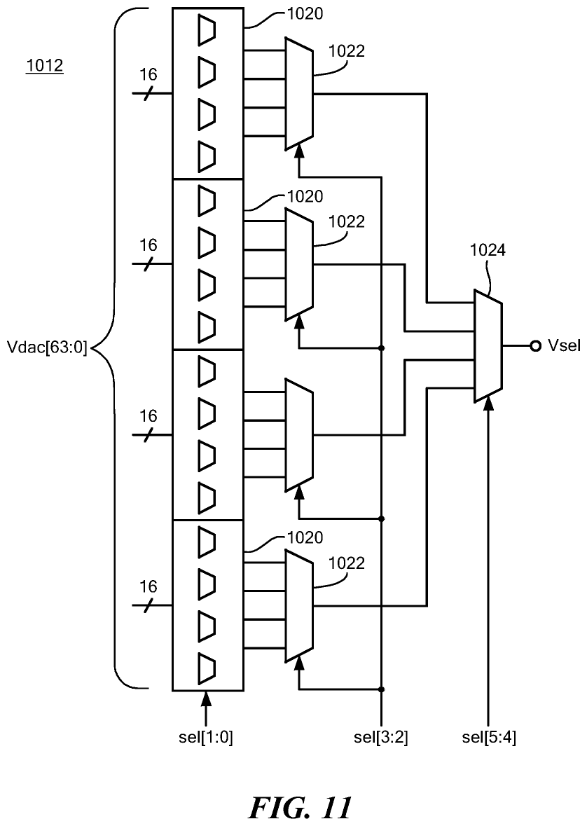

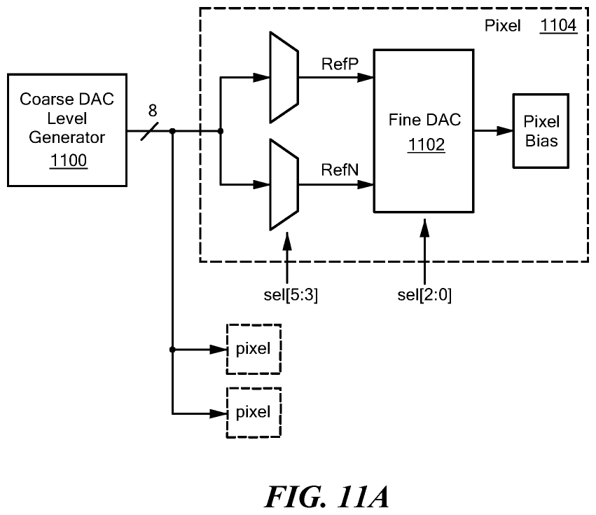

In an example embodiment shown in FIG. 11, the DAC voltage selection mux network 1012 comprises of a cascaded series of analog voltage mux selection circuits. An embodiment includes a cascaded set of 4:1 muxes 1020, where 1 DAC voltage is selected from 4 DAC input voltages and passed to following stages. The selected voltages are then passed to later identical 4:1 mux stages 1022 eventually leading to a final stage of a 4:1 mux 1024 where the output is the selected DAC voltage. This arrangement of cascaded 4:1 muxes minimizes selection decoding required in the pixel while also keeping the number of muxes required per-pixel to a manageable level. Other embodiments are possible utilizing either a different number of cascaded stages, number of DAC inputs, or width of the component mux.

Additional embodiments include implementing the entirety of the DAC inside each pixel removing the need for a DAC voltage distribution network and selection muxes. In the embodiment shown in FIG. 11A, DAC voltage generation is performed in a global DAC level generator 1100 where a coarse set of voltages is developed and delivered globally from outside the pixel and each individual pixel selects coarse DAC voltages as inputs to a fine DAC generator 1102 which develops a voltage with finer resolution that provided by the external DAC. The DAC selection may employ cascaded or flat mux 1104 selection. The distribution of coarse and fine DAC bit resolution may be adjusted depending on the needs and/or constraints of the system and/or application.

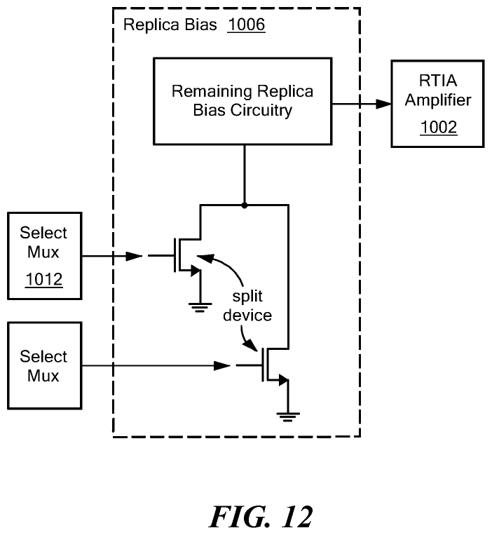

In embodiments, DAC selection resolution may be increased beyond these delivered voltages and direct selection by splitting input bias devices these voltages are meant to drive into multiple parallel devices each to be driven by separately selected DAC values thereby approximating an interpolated bias voltage setting between the discretely available DAC settings in the DAC voltage distribution network. FIG. 12 shows an example replica bias device splitting for interpolated DAC settings.

In a further aspect, a pixel gain non-uniformity measurement and calibration circuit is provided. Photo-diodes manufactured in arrays may have device-to-device variation that is often significant so as to require some form of non-uniformity correction (NUC). This is conventionally done in post-processing after images are captured. In the case of avalanche photo-diode (APD) arrays, post-processing correction is undesirable because the variation in gain can be quite substantial and may severely limit the uniformity of sensitivity across the receiver. Known calibration methods often employed for this correction are extremely difficult to get right as it is very difficult to measure APD gain with transient calibration inputs that need to be uniform in amplitude and bandwidth across the entire array.

Embodiments of the disclosure include reconfiguring the differential active pixel circuit meant to measure transient pulses into a circuit capable of presenting differential voltages proportional to photo-diode photo-current. With this configuration, a simple light source in an integrating sphere can be used to calibrate the APD gains. Additionally, the calibration can be iterated in this configuration to drive the relative gain difference between the APDs quite low. The calibration circuit may allow each pixel to be independently biased while maintaining maximum sensitivity performance by not further loading the front-end amplifier inputs.

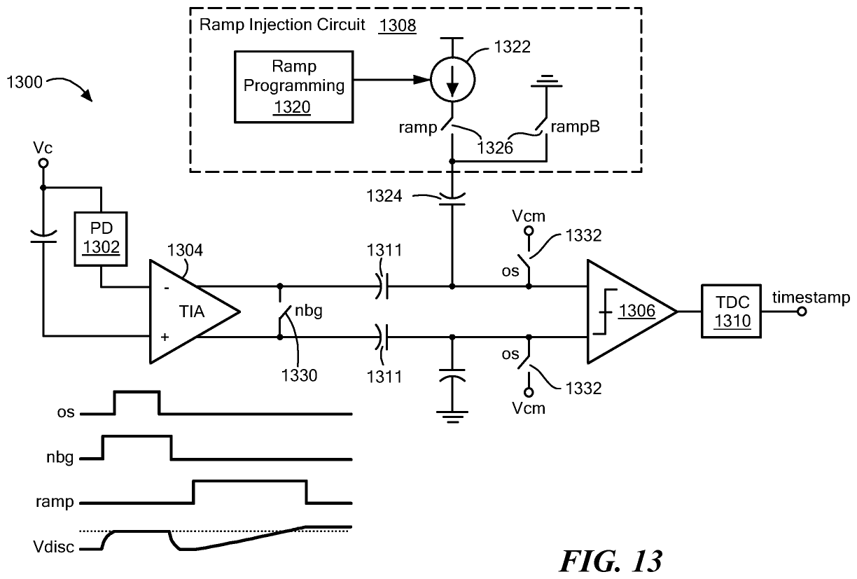

FIG. 13 shows an example implementation of a non-uniformity measurement circuit 1300 including a photo-detector diode 1302 coupled to a differential front-end pixel transimpedance amplifier 1304 that feeds a voltage level discriminator 1306. An auxiliary voltage ramp generation circuit 1308 can be coupled to the input of the voltage level discriminator 1306. Control switches can enable reconfiguring and operation of the pixel in the calibration measurement mode. A time-to-digital converter (TDC) 1310 receives the output of the voltage level discriminator 1306.

The photo-detector (PD) diode 1302 generates photo-current proportional incident photon flux. If the PD is an avalanche photo-diode (APD) the voltage bias across the terminals will modulate the gain of the diode. The gain of the APD at a given bias will vary from device-to-device due to manufacturing variation.

The front-end pixel transimpedance amplifier (TIA) 1304 converts photo-diode 1302 current inputs into voltage outputs and may contain additional voltage gain stages to further increase the transimpedance gain. The voltage gain stage is not required but may improve the sensitivity of the detector system. The front-end TIA 1304 may be configurable to produce a negative differential voltage proportional to the background current for the calibration mode.

In embodiments, the voltage level discriminator 1306 compares two analog voltage inputs and produces a digital output whenever the positive input exceeds the voltage of the negative input. The output of the analog front end amplifying stage is connected to the discriminator 1306 directly or through AC-coupling capacitors 1311. With the negative differential voltage input on the discriminator 1306 inputs a positive input must be provided with sufficient amplitude to overcome the negative input and trigger a high-to-low logical transition on the output of the discriminator.

In embodiments, the auxiliary voltage ramp circuit 1308 produces a voltage ramp at the positive discriminator 1306 input triggered by a timing control signal where the voltage transitions linearly from a low state to a high state at some programmable 1320 rate. In the illustrated embodiment, a current source 1322 produces constant current to flow onto a capacitor 1324. A switch 1326 connects the current source 1322 to the capacitor controlled with a timing signal. The result of this configuration is that the voltage on the capacitor 1324 rises at a rate proportional to the current setting. This current is electrically programmable allowing modification of the voltage ramp rate. This configuration may either be included in individual pixels, shared among groups of pixels, or configured as single structure delivering a ramp input to all pixels simultaneously.

The control switches may perform several tasks. One switch set (not shown) reconfigures the differential amplifier circuit so that static photo-current is represented as a negative differential value at the amplifier stage outputs (internal to front-end amplifier). Another set of switches 1330, 1332 controls input capacitor sampling in an AC-coupled implementation (nbg,os). Another set of switches 1326 controls the ramp operation (ramp,rampB).

The time-to-digital converter (TDC) 1310 produces a digital output code proportional to the time of an event with respect to another system timing reference. When the ramp injection is operational and moving on the positive discriminator input, at the point where the positive input becomes higher than the negative input, the discriminator 1306 output transitions from low-to-high. This output transition is timed with the TDC 1310 to produce a time stamp corresponding to the time it took for the ramp to overcome the negative differential voltage presented at the discriminator input, which is derived from the static photo-diode current and a measurement of the relative APD gain under uniform illumination.

In embodiments, a calibration measurement is taken for the relative times between each pixel that is directly proportional to APD gain variation under uniform illumination. A successful calibration utilizing the example photo-diode calibration circuitry described above, results in repeated calibration measurements with substantially identical time stamp results. An iterative process may be employed where calibration settings are modified, and the calibration measurement is repeated to determine the remaining correction required. After several repetitions of this pattern, the calibration measurement will approach a difference of zero between all pixel time stamp measurements and the APD gain will be matched for each pixel.

In an alternative embodiment, instead of inverting the output of the TIA stage, the differential ramp direction of travel may be changed by inverting the ramp injection direction or coupling the ramp injection circuit to the opposite differential node. In this case, the discriminator output will start high and transition to low when the differential discriminator positive input goes below the negative input. The high-to-low crossing is then timed with a time-to-digital converter and used as the calibration reference for the pixel.

In another aspect, a pixel damage threshold extension circuit is provided. Analog photo-detector front ends are sensitive to damage from excessive photo-current from photo-diodes under bright illumination. The addition of conventional protection circuits keeps these large currents (both static and transient) from doing damage to the sensitive devices in the input amplifiers. These conventional protection circuits are often large diodes that add significant capacitive loading on the amplifier inputs and increase circuit noise and reduce circuit bandwidth, both ultimately degrading sensitivity of the detection system.

Embodiments of the disclosure utilize a differential resistive transimpedance amplifier (RTIA) with common mode feedback and additional input-output shorting diodes for controlling the amount of photo current that can be injected to the amplifier input before damage occurs on the input devices.

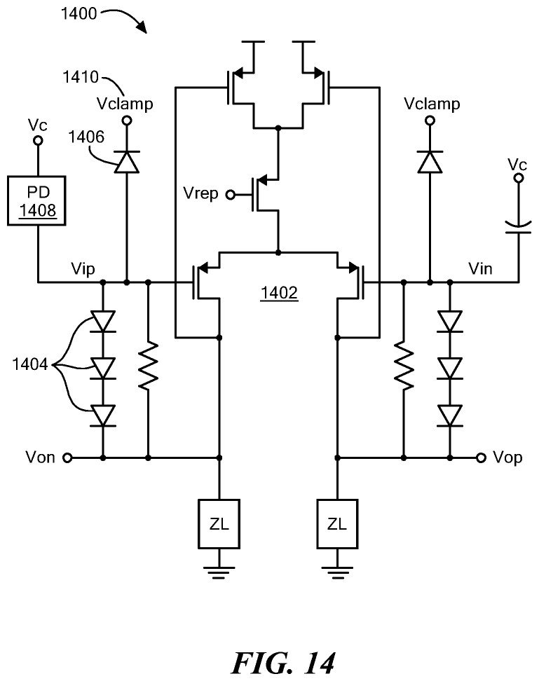

FIG. 14 shows an example circuit 1400 for reducing pixel damage including a differential resistive transimpedance amplifier 1402 having a common mode feedback control mechanism. Input protection diodes 1406 are connected to a dedicated clamping power supply 1410. A photo-diode 1408 is coupled to an input of the RTIA 1402.

The differential resistive transimpedance amplifier (RTIA) 1402 utilizes a direct-coupled common mode feedback mechanism which quickly adjusts the amplifier current in response to photo-current from the photo-diode 1408. Under a large current input, the common-mode feedback forces the amplifier 1402 to increase current and raise node voltages limiting differential voltage that is allowed to develop across transistors delaying damage to amplifier devices.

The input protection diodes 1406 provide a current path to a clamping power supply (or ground) when the forward bias voltage of the diode is exceeded.

The input-output shorting diode structure 1404 provides an alternative current path from the input Vip, Vin to output Von, Vop nodes when the input-output voltage difference exceeds the total forward bias of the diode structure. This diode structure is comprised of several series diodes 1404 which forward bias drop add together to form an aggregate diode forward voltage drop larger than a single diode. The number of diodes 1404 used is series depends on the desired protection level and the desired RTIA amplifier 1402 swing before voltage clamping becomes engaged. When this aggregate diode forward voltage drop is exceeded, the diode structure conducts current forcing the input node to conduct current to the output node. This current in-turn modifies the output voltage and, by-way of the common-mode feedback circuit, modifies the bias of the amplifier 1402 forcing a portion of the input-output shorted current into the power supply though the amplifier. This additional current path provides increased excess current sinking capacity for relatively low input capacitive loading thereby improving the sensitivity and increasing the allowable photo-diode 1408 input current before damage occurs to the sensitive amplifier devices.

In another aspect, a damage threshold exceedance detection circuit is provided. When a photo-diode provides a too-high photo-current input to an amplifier front-end, irreparable damage may develop in the amplifier devices rendering the amplifier either non-functional or severely performance limited. Additionally, this damage can be severe enough to damage an entire ASIC.

It is desirable to detect when input photo-current levels are approaching this damage threshold so that a system might intervene and modify operation to reduce photo-current before permanent damage is accumulated. Such a system may reduce customer returns of faulty products and may also open up product spaces and applications where high likelihood of too-large photo-detector inputs exist.

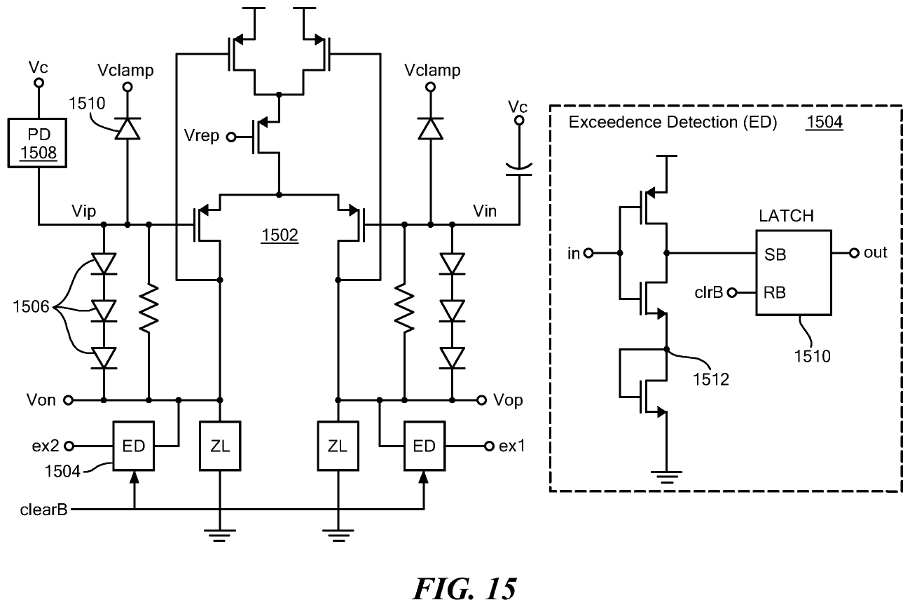

FIG. 15 shows an example circuit 1500 implementing damage threshold exceedance including a pixel front-end resistive transimpedance amplifier 1502 coupled to a low-capacitive loading voltage exceedance detection and latch circuit 1504. Diode protection circuitry can include input-output current path diodes 1506.

The resistive transimpedance amplifier (RTIA) circuit 1502 converts detector photo-current (both static and transient) from a photo-diode 1508 into corresponding voltages. This can be accomplished with a simple single-ended amplifier with resistive feedback or with a more complicated differential RTIA structure with common-mode feedback.

In embodiments, the voltage exceedance detection (ED) circuitry 1504 utilizes transistor built-in threshold voltages to only allow triggering when a sufficiently large input is provided. The design can be tuned for a desired voltage by adding additional devices in the thresholded inverter 1512 or by sizing devices in the thresholded inverter 1512 appropriately; however, tuning the voltage trigger to be near the power supply levels may be effective as the exceedance only triggers when there is a sufficiently large input that risks damaging the amplifier devices. When a voltage exceedance occurs, the record of this exceedance may be stored in a latch 1510 and made available for later retrieval by a polling circuit. A control signal may be used to reset the latch after checking for exceedance occurrences.

Diode protection circuits 1506 provide a path for excess photo-current to flow with a relatively small increase in input voltage. This provides a larger range of current inputs where damage threshold exceedance may be detected before damage occurs to the amplifier devices.

The differential RTIA 1502 allows the placement of the voltage exceedance detection circuit 1504 on both positive and negative outputs of the RTIA. With this configuration, the amplifier output saturation (ex1) is detected on the positive output which indicates a large signal, but not necessarily a dangerously large signal. The negative output voltage exceedance circuit (ex2), however, only detects an exceedance when the signal is so large that all protection diodes 1506,1510 current paths become saturated and a damaging over-voltage condition is imminent. Use of both voltage exceedance detections circuits can be used to observe relative input levels even when they exceed the dynamic range of the input amplifiers.

Embodiments of the disclosure can be implemented in hardware, firmware, and software, and in combinations thereof. Processing may be implemented in computer programs executed on programmable computers/machines that each includes a processor, a storage medium or other article of manufacture that is readable by the processor (including volatile and non-volatile memory and/or storage elements), at least one input device, and one or more output devices. Program code may be applied to data entered using an input device to perform processing and to generate output information.

The system can perform processing, at least in part, via a computer program product, (e.g., in a machine-readable storage device), for execution by, or to control the operation of, data processing apparatus (e.g., a programmable processor, a computer, or multiple computers). Each such program may be implemented in a high-level procedural or object-oriented programming language to communicate with a computer system. However, the programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., RAM/ROM, CD-ROM, hard disk, or magnetic diskette) that is readable by a general or special purpose programmable computer for configuring and operating the computer when the storage medium or device is read by the computer.

Processing may also be implemented as a machine-readable storage medium, configured with a computer program, where upon execution, instructions in the computer program cause the computer to operate.

Processing may be performed by one or more programmable processors executing one or more computer programs to perform the functions of the system. All or part of the system may be implemented as, special purpose logic circuitry (e.g., an FPGA (field programmable gate array) and/or an ASIC (application-specific integrated circuit)).

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A pixel system for providing power supply noise rejection, comprising:
a photodetector having a first terminal coupled to a voltage supply and a second terminal;
a differential transimpedance amplifier having a first input coupled to the second terminal of the photodetector, wherein the differential transimpedance amplifier is configured to convert a singled ended output on the second terminal of the photodetector to a differential signal; and
a bias circuit coupled to the differential transimpedance amplifier to bias the differential transimpedance amplifier and the photodetector.

2. The system according to claim 1, further including a tuning capacitor having first and second terminals, wherein a second input of the differential transimpedance amplifier is coupled to a second terminal of the tuning capacitor.

3. The system according to claim 1, wherein the differential transimpedance amplifier comprises a RTIA, CTIA, CTIA and/or shaper.

4. The system according to claim 1, wherein the photodetector comprises a photodiode.

5. The system according to claim 1, further including wherein the bias circuit is configured to maintain selected respective first and second bias voltages at the first input and a second input of the differential transimpedance amplifier with a feedback network coupled to the differential transimpedance amplifier.

6. The system according to claim 5, wherein the selected bias voltages comprise selected common mode voltage bias levels.

7. The system according to claim 6, wherein the first bias voltage is configured to define a bias voltage on the photodetector, which comprises a photodiode.

8. The system according to claim 7, wherein the first bias voltage is configured to force a single-ended current from the photodiode into a differential output voltage from the differential transimpedance amplifier.

9. The system according to claim 5, wherein the feedback network comprises first and second resistors coupled across the respective differential outputs and first and second inputs of the differential transimpedance amplifier.

10. The system according to claim 1, further including a tuning capacitor having first and second terminals, wherein a second input of the differential transimpedance amplifier is coupled to a second terminal of the tuning capacitor, wherein the tuning capacitor has a capacitance matched to a capacitance of the photodetector.

11. The system according to claim 1, wherein the bias circuit forms part of a pixel.

12. The system according to claim 1, including further photodetectors and further bias circuits configured to provide independent biasing of pixel photodetectors in an array of photodetectors.

13. The system according to claim 1, further including at least one clamping diode coupled between the input and an output of the differential transimpedance amplifier.

14. The system according to claim 13, wherein the system is configured such that when an aggregate diode forward voltage drop across the at least one clamping diode is exceeded, at least one clamping diode conducts current forcing the input of the differential transimpedance amplifier to conduct current to the output of the differential transimpedance amplifier.

15. The system according to claim 14, wherein the system is further configured such that the current from the input to the output of the differential transimpedance amplifier modifies an output voltage of the differential transimpedance amplifier and by-way of the common-mode feedback modifies the bias of the differential transimpedance amplifier to force a portion of the input-output shorted current into a power supply though the differential transimpedance amplifier.

16. The system according to claim 1, further including a damage threshold exceedance detection circuit to detect when the photodetector provides a photo-current input above a threshold.

17. The system according to claim 16, wherein the damage threshold exceedance detection circuit comprises at least one clamping diode coupled between the input and an output of the differential transimpedance amplifier, wherein the damage threshold exceedance detection circuit includes a latch to store an alert.

18. A method, comprising:
in a pixel system for providing power supply noise rejection,
employing a photodetector having a first terminal coupled to a voltage supply and a second terminal;
employing a differential transimpedance amplifier having a first input coupled to the second terminal of the photodetector, wherein the differential transimpedance amplifier is configured to convert a singled ended output on the second terminal of the photodetector to a differential signal; and
employing a bias circuit coupled to the differential transimpedance amplifier to bias the differential transimpedance amplifier and the photodetector.

19. The method according to claim 18, further including employing a tuning capacitor having first and second terminals, wherein a second input of the differential transimpedance amplifier is coupled to a second terminal of the tuning capacitor.

20. The method according to claim 18, wherein the differential transimpedance amplifier comprises a RTIA, CTIA, CTIA and/or shaper.

21. The method according to claim 18, wherein the photodetector comprises a photodiode.

22. The method according to claim 18, further including wherein the bias circuit is configured to maintain selected respective first and second bias voltages at the first input and a second input of the differential transimpedance amplifier with a feedback network coupled to the differential transimpedance amplifier.

23. The method according to claim 22, wherein the selected bias voltages comprise selected common mode voltage bias levels.

24. The method according to claim 23, wherein the first bias voltage is configured to define a bias voltage on the photodetector, which comprises a photodiode.

25. The method according to claim 24, wherein the first bias voltage is configured to force a single-ended current from the photodiode into a differential output voltage from the differential transimpedance amplifier.

26. The method according to claim 22, wherein the feedback network comprises first and second resistors coupled across the respective differential outputs and first and second inputs of the differential transimpedance amplifier.

27. The method according to claim 18, further including employing a tuning capacitor having first and second terminals, wherein a second input of the differential transimpedance amplifier is coupled to a second terminal of the tuning capacitor, wherein the tuning capacitor has a capacitance matched to a capacitance of the photodetector.

28. The method according to claim 18, wherein the bias circuit forms part of a pixel.

29. The method according to claim 18, including further employing photodetectors and further bias circuits configured to provide independent biasing of pixel photodetectors in an array of photodetectors.

30. The method according to claim 18, further including employing at least one clamping diode coupled between the input and an output of the differential transimpedance amplifier.

31. The method according to claim 30, further including configuring the system such that when an aggregate diode forward voltage drop across the at least one clamping diode is exceeded, at least one clamping diode conducts current forcing the input of the differential transimpedance amplifier to conduct current to the output of the differential transimpedance amplifier.

32. The method according to claim 31, further including configuring the system such that the current from the input to the output of the differential transimpedance amplifier modifies an output voltage of the differential transimpedance amplifier and by-way of the common-mode feedback modifies the bias of the differential transimpedance amplifier to force a portion of the input-output shorted current into a power supply though the differential transimpedance amplifier.

33. The method according to claim 18, further including employing a damage threshold exceedance detection circuit to detect when the photodetector provides a photo-current input above a threshold.

34. The method according to claim 33, wherein the damage threshold exceedance detection circuit comprises at least one clamping diode coupled between the input and an output of the differential transimpedance amplifier, wherein the damage threshold exceedance detection circuit includes a latch to store an alert.
